(19) United States
(12) Patent Application Publication
(10) Pub. No.: US 2006/0003268 A1
(43) Pub. Date: Jan. 5, 2006

(54) Method of forming semiconductor patterns

(75) Inventors: Jin Hong, Hwaseong-gun (KR); Myoung-Ho Jung, Yonging-si (KR); Hyun-Woo Kim, Hwaseong-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/155,341

(22) Filed: Jun. 17, 2005

(30) Foreign Application Priority Data
Jun. 17, 2004 (KR) 04-45052

(51) Int. Cl. G03F 7/36

(52) U.S. Cl. 430/323; 430/322

(57) ABSTRACT

A method of forming a pattern comprises the steps of stacking an inorganic hard mask layer, an organic mask layer, and an anti-reflecting layer on a substrate where a lower layer is formed, forming a photoresist pattern containing silicon on the anti-reflecting layer, performing an O₂ plasma ashing to form a conformal layer of an oxide glass on the photoresist pattern containing silicon and to dry etch the anti-reflecting layer and the organic mask layer to form an anti-reflecting pattern and an organic mask pattern, removing the photoresist pattern, the anti-reflecting pattern, and the organic mask pattern, and etching the lower layer using a pattern of the inorganic hard mask layer as an etch mask.

### CROSS-REFERENCE TO RELATED APPLICATION

This application claims priority to Korean Patent Application No. 2004-45052, filed on Jun. 17, 2004, the disclosure of which is herein incorporated by reference in its entirety.

### TECHNICAL FIELD

This disclosure relates to methods of fabricating semiconductor devices, and more particularly to methods of forming semiconductor patterns.

### BACKGROUND

In general, methods for forming semiconductor devices utilize photolithography methods during various stages of device fabrication. Photolithography generally includes forming a photoresist layer on a lower layer, forming a photoresist pattern by photolithography and etching processes, and patterning the lower layer using the photoresist pattern as an etch mask.

Conventionally, an anti-reflecting layer may be formed before forming a photoresist layer to prevent reflection of an exposure-beam. The anti-reflecting layer does not have a photosensitivity characteristic and is formed of an organic material like a photoresist layer. A wavelength of the exposure beam becomes shorter as integration of devices increases. Thus, a thin photoresist layer receiving the short wavelength is desirable. To provide sufficient etching tolerance in etching the lower layer, a hard mask layer is formed on the lower layer. Then, the hard mask layer is patterned to form a hard mask pattern. Then, the lower layer is etched using the hard mask pattern as an etch mask.

To reduce the size of transistors while securing current capacity of the transistor, 3-dimensional transistors or multi-channel structure transistors have been developed.

FIGS. 1A to 1E illustrate a method for fabricating the transistor having a multi-channel structure by a conventional pattern formation method. With reference to FIG. 1A, a semiconductor substrate 10 is patterned to form an active region 10a, which is vertically extended. A gate insulating layer 11, a gate conductive layer 12, a hard mask layer 14, and an anti-reflection layer 18 are sequentially formed on the semiconductor substrate 10 where the active region 10a is formed. A photoresist pattern 20p is formed on the anti-reflecting layer 18. As shown in FIG. 1A, the gate conductive layer 12 and the hard mask layer 14 are not flat, and the anti-reflecting layer 18 is formed on non-flat surface of the hard mask layer 14. Then, the anti-reflecting layer 18 is planarized. In general, silicon oxynitride can be used as the hard mask layer 14, and an organic layer having no photosensitivity can be used as the anti-reflecting layer 18.

With reference to FIGS. 1A and 1B, the anti-reflecting layer 18 is etched using the photoresist pattern 20p as an etch mask to form an anti-reflecting pattern 18p. The anti-reflecting layer 18 formed between the active regions 10a is thicker than anti-reflecting layer 18 formed on an upper portion of the active regions 10a. To remove the anti-reflecting layer 18 between the active regions 10a, an over-etching is performed. As a result, as shown in FIG. 1B, the photoresist pattern 20p is damaged so that a poor pattern such as the reduction of the thickness and width of the photoresist pattern 20p is created. Etching damage also occurs to the hard mask layer 14 over the active regions 10a.

With reference to FIG. 1C, the hard mask layer 14 (FIG. 1B) is continuously etched to form a hard mask pattern 14p. The photoresist pattern 20p becomes more damaged, and the shape of the hard mask pattern 14p is also deformed. The deformation of the hard mask pattern 14p becomes more serious on the upper portion of the active regions 10a. In addition, due to a continuous over-etching, which started from the etching process for the anti-reflecting layer 18 (FIG. 1A), etching damages occur to a gate conductive layer 12 over the active region 10a. Due to this problem, during a trim process in which the gate line width on the active region 10a becomes narrower, a cut-off of a gate pattern 12p (FIG. 1D) may occur.

With reference to FIGS. 1C and 1D, the photoresist pattern 20p and the anti-reflecting pattern 18p are removed to expose the hard mask pattern 14p. As shown in FIG. 1D, the line width of the hard mask pattern 14p over the active region 10a is shortened by an over-etching, and a profile of the hard mask pattern becomes poor. The gate conductive layer 12 is etched using the hard mask pattern 14p as an etch mask to form a gate pattern 12p. Due to etching damages created from the process of etching the anti-reflecting pattern 18p, the gate insulating layer 11 is over-etched, and etching damages occur to an upper surface of the active region 10a vertically extended. The active region is over-etched along the edge of the gate pattern 12p so that dents may occur.

With reference to FIGS. 1D and 1E, the hard mask pattern 14p is removed to expose the gate pattern 12p. According to a conventional art as shown in FIG. 1E, the thickness of the lower layer becomes changed by a step difference of the active region 10a. Thus, during etching a thick lower layer, a thin lower layer is over etched so that the profile of the gate pattern becomes poor. When the line width of the gate is narrow, the gate line can be cut or becomes thin, which causes an increase of resistance.

### SUMMARY OF THE INVENTION

In an exemplary embodiment of the present invention, a method of forming a pattern comprises the steps of stacking an inorganic hard mask layer, an organic mask layer, and an anti-reflecting layer on a substrate where a lower layer is formed, forming a photoresist pattern containing silicon on the anti-reflecting layer, performing an O₂ plasma ashing to form a conformal layer of an oxide glass on the photoresist pattern containing silicon and to dry etch the anti-reflecting layer and the organic mask layer to form an anti-reflecting pattern and an organic mask pattern, removing the photoresist pattern, the anti-reflecting pattern, and the organic mask pattern, and etching the lower layer using a pattern of the inorganic hard mask layer as an etch mask.

In another exemplary embodiment of the present invention, a method of forming a semiconductor pattern comprises the steps of conformally forming a gate insulating layer, a gate conductive layer, and an inorganic hard mask layer on a substrate where an active region vertically extended is formed, forming a planarized organic mask layer and an anti-reflecting layer on the inorganic hard mask layer, forming a photoresist pattern containing silicon on the anti-reflecting layer, performing an O₂ plasma ashing to form a conformal layer of an oxide glass over the photoresist pattern containing silicon and to dry etch the anti-reflecting layer and the organic mask layer to form an anti-reflecting pattern and an organic mask pattern, patterning the inorganic hard mask layer to form a hard mask pattern using the photoresist pattern containing silicon, the anti-reflecting layer, and the organic mask layer as an etch mask, removing the photoresist pattern, the anti-reflecting pattern, and the organic mask pattern, etching the gate conductive layer to form a gate pattern using the hard mask pattern as an etch mask, and removing the hard mask pattern.

These and other exemplary embodiments, features and advantages of the present invention will become more apparent by describing in detail exemplary embodiments thereof with reference to the attached drawings.

### BRIEF DESCRIPTION OF THE DRAWINGS

FIGS. 1A to 1E show a method of forming a semiconductor pattern according to a conventional technology.

FIG. 2 is a flowchart illustrating a method of forming the semiconductor pattern according to an exemplary embodiment of the present invention.

FIGS. 3A to 3F illustrate a method of forming the semiconductor pattern according to an exemplary embodiment of the present invention.

FIGS. 4A to 4F illustrate a method of forming the semiconductor pattern according to another exemplary embodiment of the present invention.

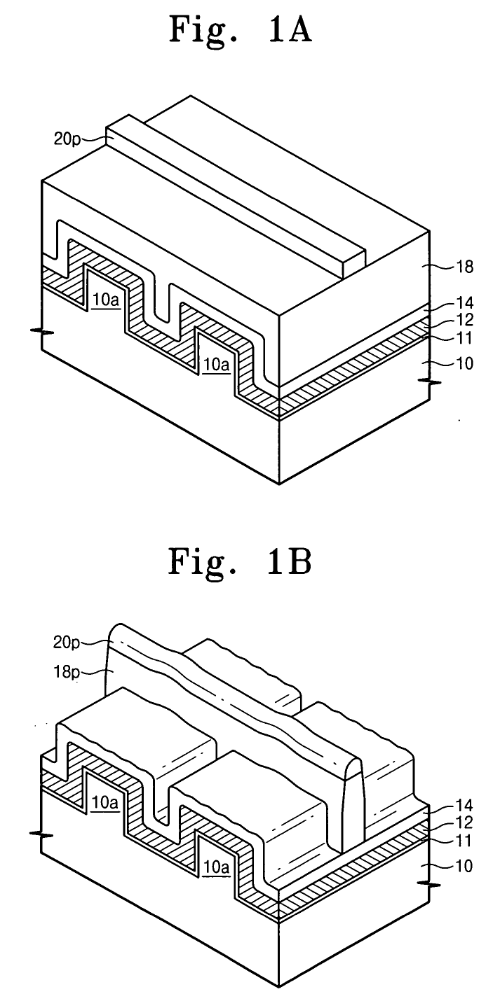

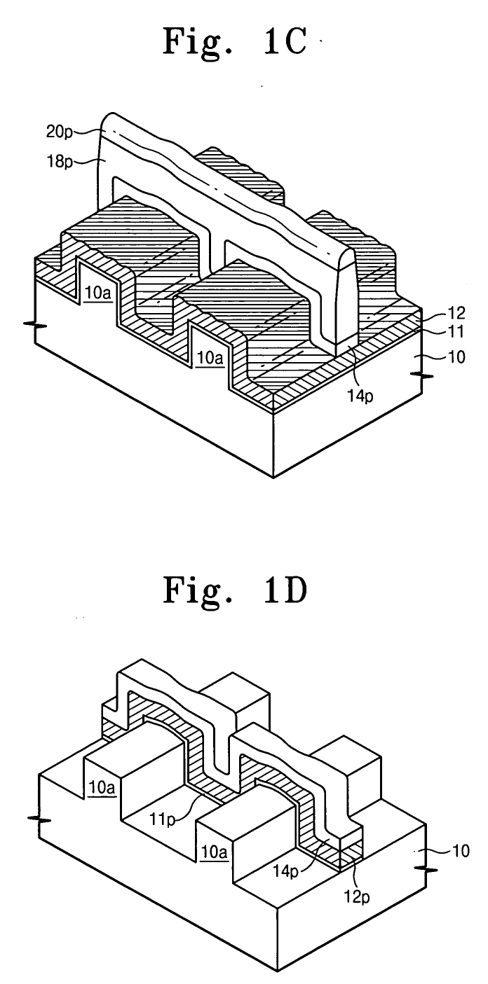

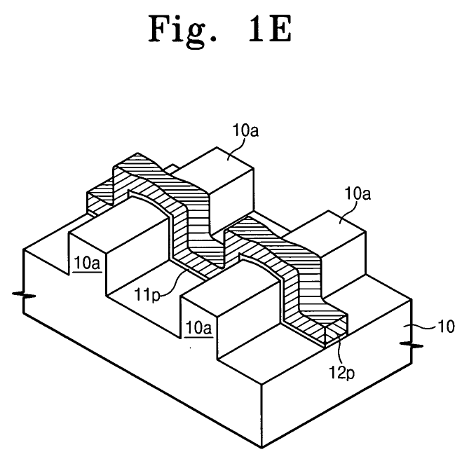

### DESCRIPTION OF EXEMPLARY EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, shapes of some elements are exaggerated for clarity.

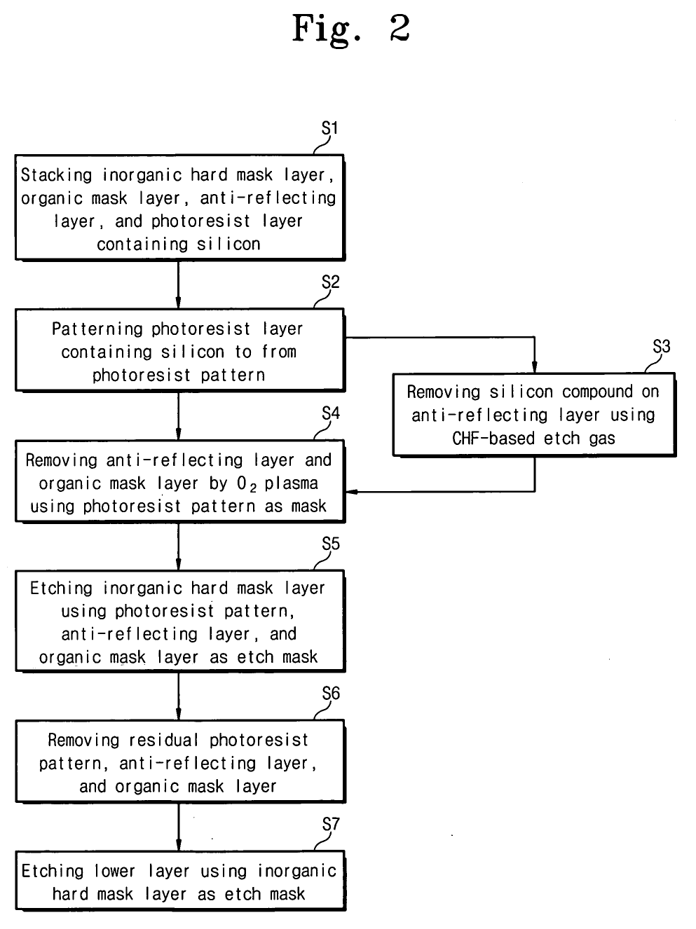

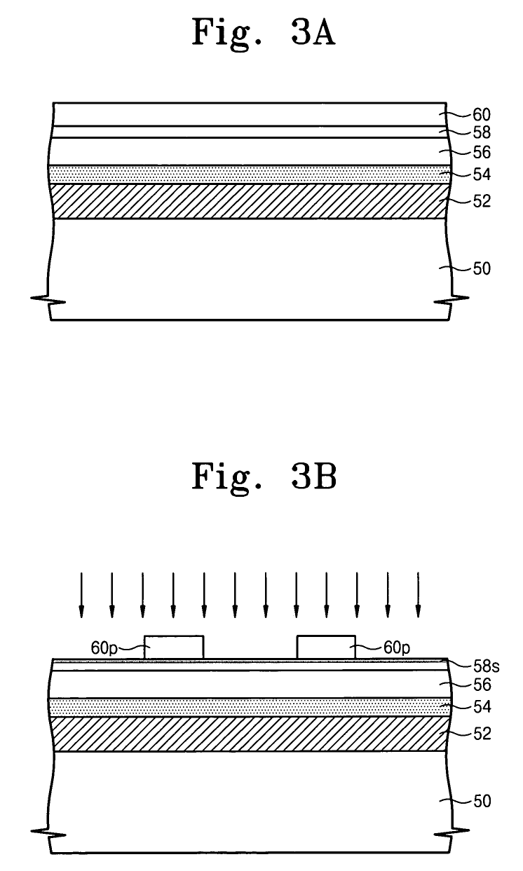

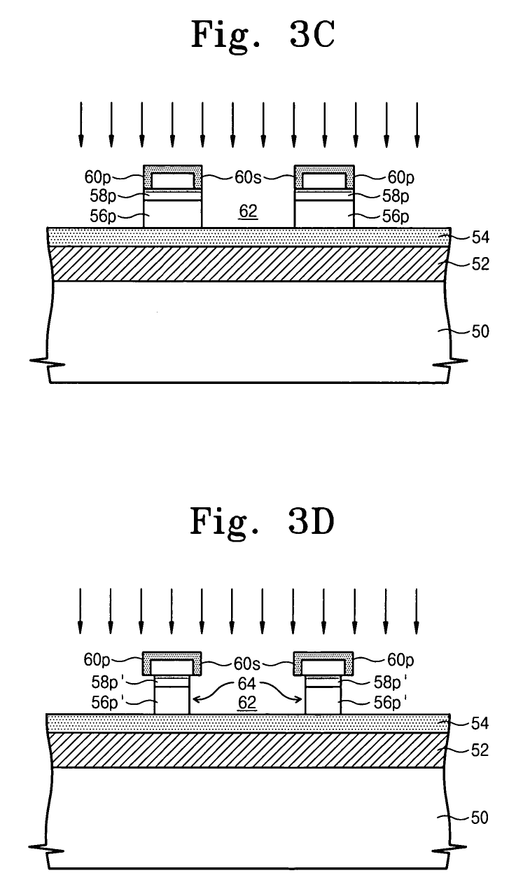

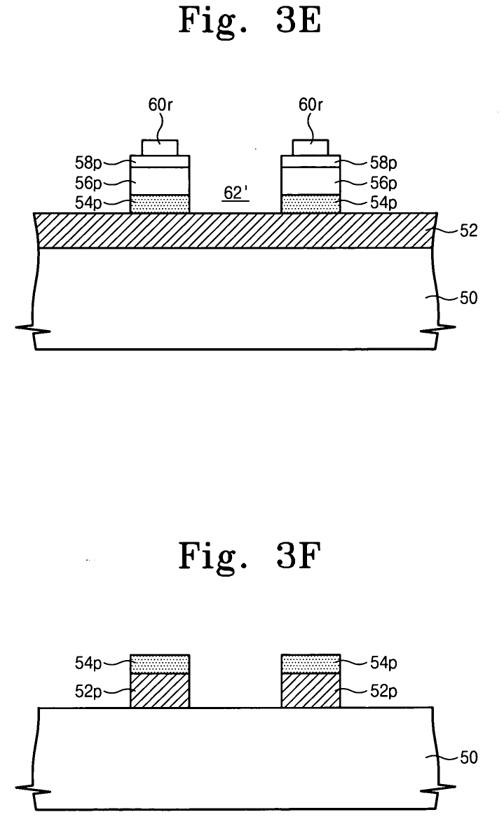

FIG. 2 is a flowchart illustrating a method of forming a semiconductor pattern in an exemplary embodiment of the present invention. FIGS. 3A to 3F illustrate a method of forming the semiconductor pattern according to an embodiment of the present invention.

Referring to S1 step of FIG. 2 and FIG. 3A, an inorganic hard mask layer 54, an organic mask layer 56, an anti-reflecting layer 58, and a photoresist layer 60 containing silicon are sequentially stacked on a substrate 50 where a lower layer 52 is formed. The hard mask layer 54 may be silicon oxynitride or silicon nitride. The organic mask layer 56 has strong tolerance with respect to a plasma for removing the hard mask layer 54. The organic mask layer 56 may be formed of, for example, SiLK without silicon, Novolak, Spin on Carbon, or naphthalene based organic material. The anti-reflecting layer 58 may be formed of general organic Anti-reflection Coating(ARC) having low reflectivity. Since the anti-reflecting layer 58 has a strong cross-link, silicon may be diffused minimally compared to a general organic layer or a photoresist layer. The photoresist layer 60 containing silicon may be an ArF, a KrF, or an F2 photoresist. The organic mask layer 56 is formed with the thickness of from about 1000 Å to about 3000 Å to planarize a step difference of the substrate 50. The anti-reflecting layer 58 may be formed with the thickness of from about 250 Å to about 450 Å. The thickness of the above-mentioned materials can be changed.

Referring to S2 and S3 of FIG. 2 and FIGS. 3A and 3B, the photoresist layer 60 containing silicon is patterned to form a photoresist pattern 60p. Even though the anti-reflecting layer 58 has a strong cross-link, the silicon of the photoresist layer 60 may be diffused on a surface of the anti-reflecting layer 58. Accordingly, it is preferable that silicon compound 58s formed on the surface of the anti-reflecting layer 58 is removed using a CHF-based etch gas. Typical examples of the CHF-based gas are CHF₃, CH₃F and CH₂F₂. CF₄, Ar and O may be added to the CHF-based gas. Preferably, the silicon compound 58s is removed during from about five seconds to about thirty seconds to minimize the damage of the photoresist pattern 60p.

Referring to S4 of FIG. 2 and FIGS. 3A, 3B and 3C, the anti-reflecting layer 58 and the organic mask layer 56 are dry etched using O₂ plasma ashing. Removing the silicon compound 58s using the CHF based gas and the O₂ plasma ashing may be performed in-situ. While the O₂ plasma ashing is performed, the silicon of the photoresist pattern 60p reacts with oxygen so that the exposed surface of the photoresist pattern 60p is converted into an oxide glass 60s. While the anti-reflecting layer 58 and the organic mask layer 56 are etched, the photoresist pattern 60p containing silicon may provide an etch mask having sufficient etching tolerance. By the O₂ plasma ashing, the organic mask pattern 56p having an opening 62, where the hard mask layer 54 is exposed, and the anti-reflecting pattern 58p are formed. In an exemplary embodiment of the present invention, the O₂ plasma ashing comprises an HBr plasma.

To form a minute pattern, a trim process may be performed. As shown in FIG. 3D, while the organic mask pattern 56p and the anti-reflecting pattern 58p are dry etched, the anti-reflecting pattern 58p and the organic mask pattern 56p are recessed in a lateral direction to form an undercut 64 where the line width of the recessed anti-reflecting pattern 58p′ and the recessed organic mask pattern 56p′ is narrower than the photoresist pattern 60p.

Referring to S5 of FIG. 2 and FIGS. 3C and 3E, the inorganic hard mask layer 54 is dry etched using the photoresist pattern 60p, the anti-reflecting pattern 58p, and the organic mask pattern 56p as an etch mask. As a result, the hard mask pattern 54p having an opening 62′ where the lower layer 52 is exposed is formed. While the hard mask layer 54 is dry etched, the oxide glass 60s of the photoresist pattern 60p may be removed.

Referring to S6 and S7 of FIG. 2 and FIGS. 3E and 3F, a residual photoresist pattern 60r, the anti-reflecting pattern 58p, and the organic mask pattern 56p are removed. The lower layer 52 is etched using the hard mask pattern 54p as an etch mask to form a lower pattern 52p.

According to an exemplary embodiment of the present invention, the anti-reflecting pattern 58p and the organic mask pattern 56p are dry etched by the O₂ plasma ashing. Therefore, etching damages do not occur to the inorganic layer 54p while the organic mask pattern 56p is etched. The profile of the lower pattern 52p is good because the lower layer 52 is patterned using the hard mask pattern 54p, which has a good pattern, as an etch mask. Furthermore, the damage of the active region due to an over-etch can be prevented.

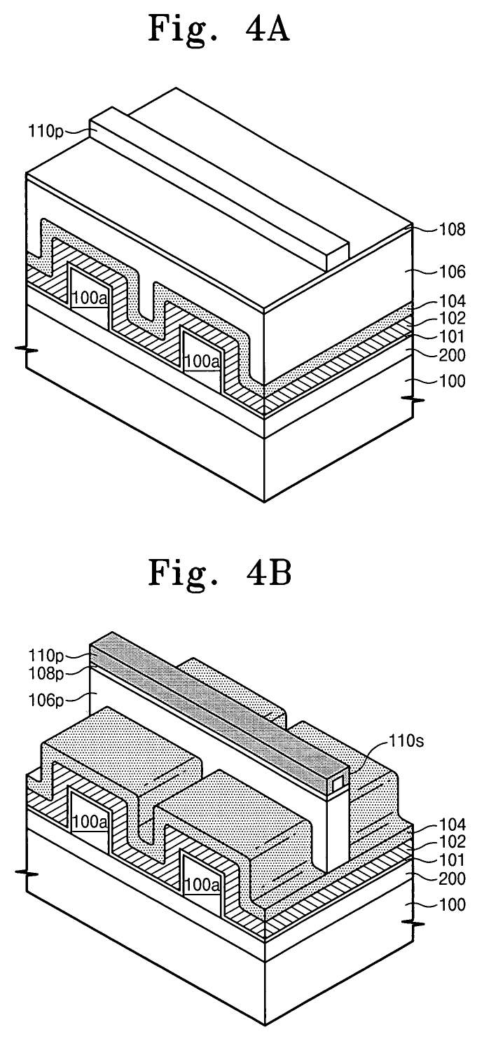

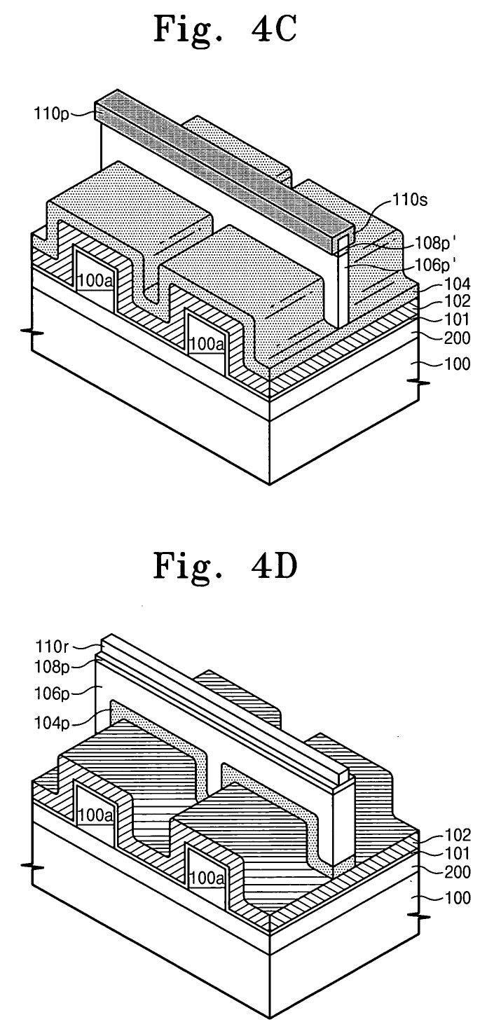

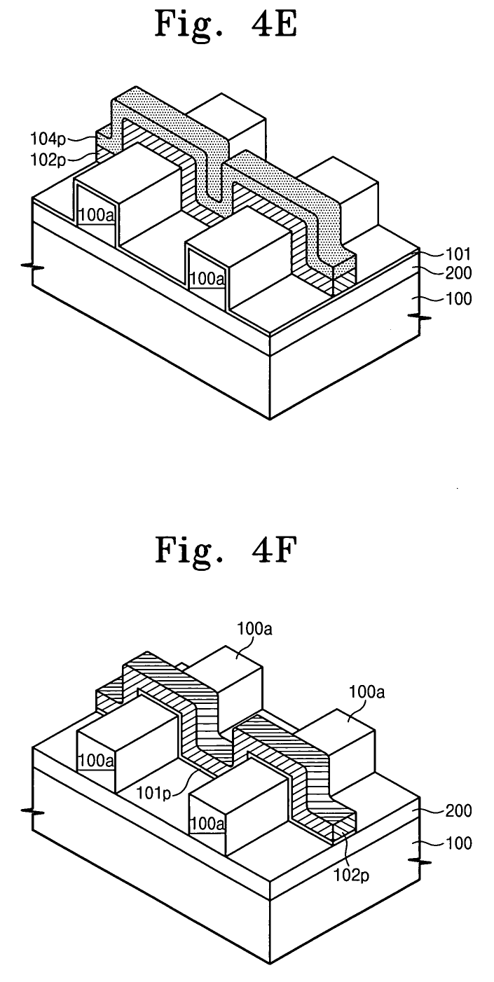

FIGS. 4A to 4F illustrate a method of forming the semiconductor pattern applied to a 3-dimensional transistor fabrication process in an exemplary embodiment of the present invention. Referring to FIG. 4A, a plurality of active regions 100a vertically extended are formed on a substrate 100. The active regions 100a may be formed using a Silicon on Insulator (SOI) substrate. That is, the semiconductor layer of an SOI substrate formed with a supporting substrate 100 and a burying insulating layer 200 is patterned to form the active regions 100a. Alternatively, active regions 100a vertically extended may be formed by forming protruded active regions and a trench by etching the substrate 100 and forming a device isolation layer between the active regions 100a.

A gate insulating layer 101, a gate conductive layer 102, and an inorganic hard mask layer 104 are formed on an entire surface of a resultant where the active regions are formed 100a. The gate conductive layer 102 may be formed of metals or semiconductors. For instance, the gate conductive layer 102 may be formed of a conductive layer such as tungsten, tungsten silicide, titanium, titanium nitride, tantalum nitride, platinum, silicon, or silicon germanium.

A planarized organic mask layer 106, which fills a gap region between the active regions 100a, is formed on the inorganic hard mask layer 104. An anti-reflecting layer 108 is formed on the organic mask layer 106. The organic mask layer 106 may be formed of a material having strong tolerance with respect to plasma for removing the hard mask layer 104. The material can be, for example, SiLK without silicon, Novolak, Spin on Carbon, or naphthalene based organic material. The anti-reflecting layer 108 may be formed of the general organic ARC having low reflectivity. Since the anti-reflecting layer 108 has a strong cross-link, silicon may be diffused minimally as compared with an organic layer or a photoresist layer. A photoresist pattern 110p crossing over the active regions 100a is formed on the anti-reflecting layer 108. The photoresist pattern 110p may comprise an ArF photoresist, a KrF photoresist, or an F2 photoresist. The organic mask layer 106 is formed in from about 1000 Å to about 3000 Å to planarize step difference of the substrate 100. The anti-reflecting layer 108 may be formed in from about 250 Å to about 450 Å. However, the thickness of the above-mentioned materials can be changed.

Referring to FIGS. 4A and 4B, the anti-reflecting layer 108 and the organic mask layer 106 are dry etched using the O₂ plasma ashing. Even though the anti-reflecting layer 108 has strong cross-link, the silicon of the photoresist layer containing silicon may be diffused on a surface of the anti-reflecting layer 108. Thus, it is preferable that silicon compound formed on the surface of the anti-reflecting layer 108 is removed using CHF based etch gas before etching the anti-reflecting layer 108. Typical examples of the CHF-based gas are CHF₃, CH₃F and CH₂F₂. CF₄, Ar and O may be added to the CHF-based gas. In an exemplary embodiment of the present invention, to minimize the damage of the photoresist layer, the silicon compound 58s removing process may be performed during about five seconds to about thirty seconds. Removing the silicon compound 58s using the CHF based gas and the O₂ plasma ashing may be performed in-situ.

While the O₂ plasma ashing is performed, the silicon of the photoresist pattern 110p reacts with oxygen so that the exposed surface of the photoresist pattern 110p is converted into an oxide glass 110s. Accordingly, while the anti-reflecting layer 108 and the organic mask layer 106 are etched, the photoresist pattern 110p containing silicon may provide an etch mask having sufficient etching tolerance.

In an exemplary embodiment of the present invention, O₂ plasma ashing is used in dry etching the anti-reflecting layer 108 and the organic mask layer 106. Accordingly, the inorganic hard mask layer 104 is not etched by the O₂ plasma ashing. While the organic mask layer 106 formed in the gap regions between the active regions 100a is etched, damage in the hard mask layer 104 over the active regions 100a can be minimized.

As shown in FIGS. 4B and 4C, the trim process may be performed to form a minute pattern. While the organic mask pattern 106p and the anti-reflecting pattern 108p are dry etched, the anti-reflecting pattern 108p and the organic mask pattern 106p are recessed in a lateral direction to form an undercut where the line width of the anti-reflecting layer 108p and the organic mask pattern 106p is narrower than the photoresist pattern 110p.

Referring to FIGS. 4B and 4D, the inorganic mask layer 104 is dry etched using the photoresist pattern 110p, the anti-reflecting layer 108p, and the organic mask pattern 106p as an etch mask. As a result, a hard mask pattern 104p for exposing the gate conductive layer 102 is formed. While the hard mask layer 104 is dry etched, the oxide glass 110s of the photoresist pattern 110p may be removed. Since the hard mask pattern 104p is formed using a mask pattern formed by the O₂ plasma ashing in an exemplary embodiment of the present invention, the hard mask pattern 104p has an excellent profile.

Referring to FIGS. 4D, 4E and 4F, a residual photoresist pattern 110r, the anti-reflecting pattern 108p, and the organic mask pattern 106p are removed. The gate conductive layer 102 is etched using the hard mask pattern 104p as an etch mask to form a gate pattern 102p. The gate insulating layer 101 is patterned to form a gate insulating pattern 101p.

According to an exemplary embodiment of the present invention, a planarized organic mask layer is etched using a photoresist containing silicon as an etch mask. As a result, a lower inorganic hard mask layer is protected while an organic mask layer is etched. There is no poor profile of a hard mask pattern. There is no poor profile of a gate pattern that is patterned using a hard mask pattern as an etching mask. An anti-reflecting layer having a strong cross-link between the photoresist, containing silicon, and an organic mask layer is capable of suppressing the remaining of a silicon compound after forming a photoresist pattern.

Although exemplary embodiments have been described herein with reference to the accompanying drawings, it is to be understood that the present invention is not limited to those precise embodiments, and that various other changes and modifications may be affected therein by one of ordinary skill in the related art without departing from the scope or spirit of the invention.

What is claimed is:

1. A method of forming a pattern comprising the steps of:
stacking an inorganic hard mask layer, an organic mask layer, and an anti-reflecting layer on a substrate where a lower layer is formed;
forming a photoresist pattern containing silicon on the anti-reflecting layer;
performing an O₂ plasma ashing to convert an exposed surface of the photoresist pattern into an oxide glass and to dry etch the anti-reflecting layer and the organic mask layer;
removing the photoresist pattern, the anti-reflecting layer, and the organic mask layer; and
etching the lower layer using the inorganic hard mask layer as an etch mask.

2. The method of claim 1, further comprising a step of removing a silicon compound on the anti-reflecting layer using a CHF-based etch gas before performing the O2 plasma ashing.

3. The method of claim 1, wherein a pattern of the anti-reflecting layer and a pattern of the organic mask layer have a narrower line width than the photoresist pattern, and the pattern of the anti-reflecting layer and the pattern of the organic mask layer are formed by etching the pattern of the anti-reflecting layer and the pattern of the organic mask layer from a lateral direction.

4. The method of claim 1, wherein the oxide glass is removed when etching the inorganic hard mask layer.

5. A method of forming a semiconductor pattern comprising the steps of:
forming a gate insulating layer, a gate conductive layer, and an inorganic hard mask layer on a substrate where an active region vertically extended is formed;
forming a planarized organic mask layer and an anti-reflecting layer on the inorganic hard mask layer;
forming a photoresist pattern containing silicon on the anti-reflecting layer;
performing an O₂ plasma ashing to convert an exposed surface of the photoresist pattern into an oxide glass and to dry etch the anti-reflecting layer and the organic mask layer;
patterning the inorganic hard mask layer to form a hard mask pattern using the photoresist pattern containing silicon, the anti-reflecting layer, and the organic mask layer as an etch mask;
removing the photoresist pattern, the anti-reflecting layer, and the organic mask layer;
etching the gate conductive layer to form a gate pattern using the hard mask pattern as an etch mask; and
removing the hard mask pattern.

6. The method of claim 5, further comprising a step of removing a silicon-contained layer on the anti-reflecting layer using a CHF-based etch gas.

7. The method of claim 6, wherein removing the silicon-contained layer on the anti-reflecting layer and performing the O₂ plasma ashing are performed in-situ.

8. The method of claim 8, wherein a pattern of the anti-reflecting layer and a pattern of the organic mask layer have a narrower line width than the photoresist pattern and, the pattern of the anti-reflecting layer and the pattern of the organic mask layer are formed by etching the pattern of the anti-reflecting layer and the pattern of the organic mask layer from a lateral direction.

9. The method of claim 5, wherein the O₂ plasma ashing comprises an HBr plasma.
